(19) United States
(12) Patent Application Publication
(10) Pub. No.: US 2026/0177603 A1
(43) Pub. Date: Jun. 25, 2026

(54) MULTIPLE SINGULATED DIE TEST STRUCTURE AND METHODS OF FORMING AND USING THE SAME

(71) Applicant: Taiwan Semiconductor Manufacturing Company Limited, Hsinchu (TW)

(72) Inventors: Chuei-Tang Wang, Taichung City (TW); Tao-Sheng Chang, Tainan City (TW); Chin-Ta Chen, Kaohsiung City (TW); Yen-Ming Chen, Hsinchu (TW); Kam Heng Lee, Hsinchu City (TW)

(21) Appl. No.: 18/991,653

(22) Filed: Dec. 22, 2024

(51) Int. Cl. G01R 31/26

(52) U.S. Cl. CPC G01R 31/2601

(57) ABSTRACT

A multiple singulated die testing structure and methods for forming the same. In some embodiments, the testing structure includes a cold plate located above an alignment stage that includes a plurality of die testing locations, a plurality of sensors, a plurality of heaters, and a plurality of vacuum sub-channels. Each heater may be located below a corresponding sensor. A vacuum channel may connect to the plurality of vacuum sub-channels located between each sensor. The testing structure may further include a multiple singulated die holder that include die grooves. In some embodiments, the multiple singulated die holder includes a high thermal conductivity material layer and a low thermal conductivity material layer.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area (i.e., footprint).

Dies may be tested for functionality and quality by a singulated die test (SDT). The SDT is used to identify defects or issues in the dies before they are assembled into a package assembly, such as integrated circuits and microprocessors. For example, the SDT may identify defects, cracks, fractures, contaminates, bonding issues, dislocations, defects in crystal structure, oxide defects, thermal defects, stress-induced defects, and sidewall cracks.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an example vertical cross-sectional view of a testing system and a probe card and multiple singulated die testing structure according to various embodiments.

FIG. 1B is an example vertical cross-sectional view of a probe card testing multiple dies in the multiple singulated die testing structure according to various embodiments.

FIG. 1C is an example bottom view of a probe card according to various embodiments.

FIG. 1D is an example top view of a sensor in a multiple singulated die testing structure according to various embodiments.

FIG. 1E is an example top view of a heater in a multiple singulated die testing structure according to various embodiments.

FIG. 2 is an example vertical cross-sectional view of a multiple singulated die testing structure with a multiple singulated die holder according to some embodiments.

FIG. 3A is an example vertical cross-sectional view of a multiple singulated die testing structure with an alternative multiple singulated die holder according to some embodiments.

FIG. 3B is an example top view of the multiple singulated die holder shown in FIG. 3A according to some embodiments.

FIG. 4A is an example vertical cross-sectional view of a multiple singulated die testing structure with an alternative multiple singulated die holder according to some embodiments.

FIG. 4B is an example top view of the multiple singulated die holder shown in FIG. 4A according to some embodiments.

FIG. 5A is an example of an intermediate structure in a process of forming a low thermal conductivity material on a substrate according to some embodiments.

FIG. 5B is an example of an intermediate structure in a process of patterning the low thermal conductivity material according to some embodiments.

FIG. 5C is an example of an intermediate structure in a process of forming a high thermal conductivity material on the patterned low thermal conductivity material according to some embodiments.

FIG. 5D is an example of an intermediate structure in a process of thinning the high thermal conductivity material according to some embodiments.

FIG. 5E is an example of an intermediate structure in a process of forming additional low thermal conductivity material according to some embodiments.

FIG. 5F is an example of an intermediate structure in a process of patterning the high thermal conductivity material according to some embodiments.

FIG. 5G is an example of an intermediate structure in a process of forming a vacuum line according to some embodiments.

FIG. 6A is an example vertical cross-sectional view of a multiple singulated die testing structure with an alternative multiple singulated die holder according to some embodiments.

FIG. 6B is an example top view of the multiple singulated die holder shown in FIG. 6A according to some embodiments.

FIG. 7A is an example of an intermediate structure in a process of patterning a cold plate according to some embodiments.

FIG. 7B is an example of an intermediate structure in a process of forming a low thermal conductivity material in the patterned cold plate according to some embodiments.

FIG. 8 is a flowchart illustrating a method of forming a multiple singulated die holder according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Disclosed embodiments relate to a multiple SDT system with thermal control solutions designed to improve the efficiency and effectiveness of semiconductor testing. Various embodiments disclosed herein may introduce a SDT structure that allows for the simultaneous testing of multiple singulated dies. In some embodiments, the SDT structure includes the use of high thermal conductivity materials for die holders, integrated sensors and heaters for precise temperature control, and/or a redesigned cooling plate with vacuum sub-channels to secure the dies during testing. By enhancing thermal management and reducing testing time, various disclosed embodiments address the limitations of traditional SDT methods, promoting more efficient and reliable fabrication testing practices.

Dies may be manufactured and diced prior to being integrated into a semiconductive device or package assembly. Initially, a wafer formed of silicon, or another substrate material may be fabricated. The wafer may be processed using photolithography, doping, and etching to form various integrated circuits. The wafer may further undergo a backgrinding process to thin the wafer to a desired thickness. Subsequently, the wafer is diced into dies by mechanical sawing, laser cutting, or stealth dicing.

Once the wafer is diced into dies, each of the dies may be tested for functionality and quality by a singulated die test (SDT). The SDT is used to identify defects or issues in the dies before the dies are assembled into a package assembly, such as integrated circuits and microprocessors. For example, the SDT may identify defects, cracks, fractures, contaminates, bonding issues, dislocations, defects in crystal structure, oxide defects, thermal defects, stress-induced defects, and sidewall cracks in the dies.

Some examples of the SDT include electrical testing, thermal testing, mechanical testing, reliability testing, and visual testing. The electrical testing may include functional testing to verify that each die performs its intended functional use and parametric testing to measure the electrical parameters like voltage, current, and resistance. Thermal testing may assess whether the die will operate within the required or design temperature ranges. Mechanical testing may assess the physical robustness of the die including mechanical stress classes. Reliability testing may include burn-in testing to identify early failures in the die when running at the elevated temperatures and voltages and temperature cycling testing that exposes the die to repeated temperature changes. Visual testing may include microscopy and imaging techniques to detect physical defects such as cracks, contaminations, or bonding issues.

In related testing processes, the SDT may use a single probe card to test each die one or two at a time. The die may be placed on a testing structure that includes a heating layer, a cold plate penetrated by a vacuum channel, and an alignment plate. In related SDT systems, the heater layer may include two sets of heater and sensors where each heater and sensor includes an inner portion and an outer portion. The heater layer and the cold plate may be separated, and the heater only operates at the beginning of the testing process.

A problem with related SDT systems is that due to only being able to test one or two dies at a time, the SDT process takes a long time to test a production run of dies. Additionally, only having two sets of heaters and sensors in the SDT system is not sufficient for achieving effective thermal control, which can result in uneven temperature profiles during testing. For example, due to rapid temperature changes during the SDT, dies may crack or delaminate. Further, temperatures gradients in dies during SDT may lead to uneven thermal expansion causing mechanical stress and die failure. Maintaining precise temperature control during the SDT may be challenging for high-powered dies. Additionally, due to poor thermal management during the SDT, improper heat dissipation may overheat the dies causing a degradation in the die's performance and reliability. Also, repeated thermal cycling during the SDT may cause fatigue in the die materials leading to long-term reliability issues.

Various embodiments relate to multiple SDT structures configured to provide thermal control that enable multiple dies to be tested simultaneously.

In some embodiments, a SDT testing structure includes a cold plate located above an alignment stage. The cold plate 106 may include a plurality of sensors, a plurality of heaters, and a vacuum channel. Each of the plurality of heaters 112 may be located below a corresponding sensor. The vacuum channel may include sub-channels through the cold plate 106 located between each sensor and configured to hold each die in place through suction (vacuum) forces. In these embodiments, the cold plate 106 may be configured to accommodate multiple dies for simultaneous testing thereby significantly shortening overall testing time and improving overall efficiency. The dies may be separated such that heat generated during SDT will not affect other dies. The sensors and heaters integrated within the cold plate may increase sensitivity to temperature changes thereby enhancing temperature control.

In some embodiments, the SDT structure may include a replaceable multiple singulated die holder configured to hold multiple dies to enable simultaneous testing of the dies while ensuring proper temperature control within the SDT testing structure. A plurality of vacuum sub-channels may be located within the cold plate and the multiple singulated die holder, with the vacuum sub-channels configured to secure dies in place on the holder during testing via suction forces. Further, the multiple singulated die holder may be secured to the cold plate by a securement vacuum sub-channel through suction forces. In these embodiments, the cold plate may be further expanded by the replaceable multiple singulated die holder to accommodate multiple dies for simultaneous testing thereby significantly shortening overall testing time and improving overall efficiency. The replaceable multiple singulated die holder may be formed to accommodate and match different shapes and sizes of the dies. The multiple singulated die holder may be formed of a material that improves heat dissipation thereby mitigating heat produced by the dies during SDT.

In some embodiments, the SDT structure may include a replaceable multiple singulated die holder with die grooves. The dies may be received by the die grooves and secured by the vacuum sub-channels by suction forces. The replaceable multiple singulated die holder is secured to the cold plate by a securement vacuum sub-channel through suction forces. In these embodiments, the multiple singulated die holder may have a thickness that is larger as compared to die holders without die grooves so as to to accommodate the die grooves. The die grooves separate the dies to further prevent heat generated by an die from affecting another die during SDT. The multiple singulated die holder may be pre-loaded with dies such that a set of dies may be placed in one holder while another set of dies are being tested in a different holder.

In some embodiments, the SDT structure may include a replaceable multiple singulated die holder with die grooves with a low thermal conductivity layer and a high thermal conductivity layer. A substrate may be located between the cold plate and the low thermal conductivity layer. The substrate may be secured to the cold plate by a substrate vacuum sub-channel through suction forces. Die grooves may be formed within the low thermal conductivity layer and the high thermal conductivity layer may be located within each die groove. The multiple singulated die holder may be replaceable to allow for pre-loading of dies or to easily replace damaged multiple singulated die holders. The addition of a high thermal conductivity and a low thermal conductivity layer with differing thermal conductivities may reduce thermal interactions between the dies. For example, the low thermal conductivity layer will prevent heat generated from one die from affecting another die while the high thermal conductivity layer provides proper heat transfer between the die and substrate.

In some embodiments, the SDT structure may include a low thermal conductivity layer and a high thermal conductivity layer located within the cold plate. Die grooves may be formed within the low thermal conductivity layer and the high thermal conductivity layer may be located within each die groove. The low thermal conductivity layer may act as a thermal barrier between the dies thereby reducing the mutual heat generation effects during SDT. The high thermal conductivity layer may enhance temperature control of the heaters and therefore the cold plate.

In a further embodiment, the SDT structure may be formed by a method that includes forming a low thermal conductivity layer and patterning the low thermal conductivity layer to form grooves. The SDT structure may separate dies thereby preventing heat generated by one die from affecting another die, ensuring proper temperature management during the SDT. A high thermal conductivity layer may be formed in the patterned low thermal conductivity layer. The high thermal conductivity layer may be thinned to be co-planar with the low thermal conductivity layer. Additional low thermal conductivity layer may be formed above the low thermal conductivity layer and the high thermal conductivity layer. Finally, the low thermal conductivity layer may be patterned to form the die grooves with the high thermal conductivity layer located at a bottom surface of the die grooves.

Various embodiments disclosed herein provide multiple advantages and improvements. For example, various embodiments include singulated die holders that carry multiple dies significantly reducing overall testing time of testing multiple dies. Additionally, various embodiments may enhance thermal control capabilities by integrating multiple sensors and multiple heaters in the cold plate. Various embodiments improve precise temperature control during testing by removing the heater layer of conventional SDT systems. As a result, various embodiments reduce thermal stress, improve thermal expansion, minimize testing defects, and improve performance and reliability of multiple dies undergoing SDT simultaneously.

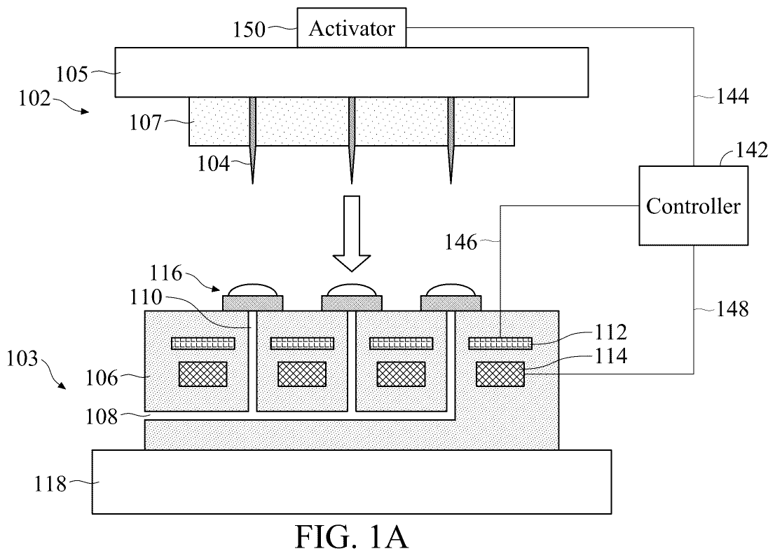

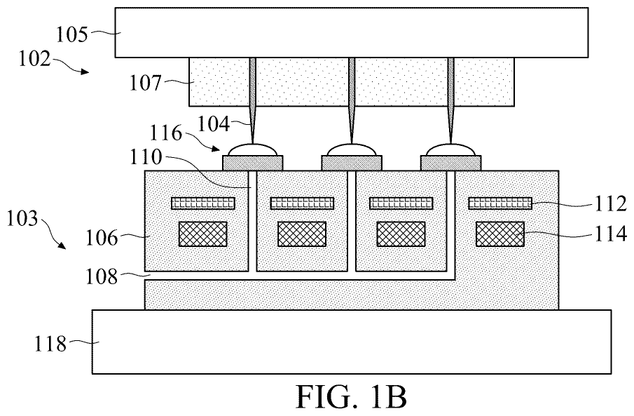

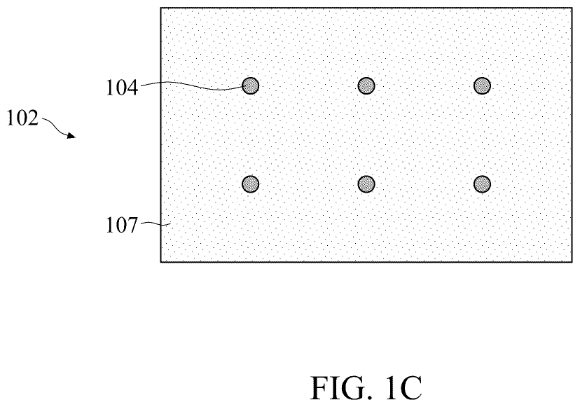

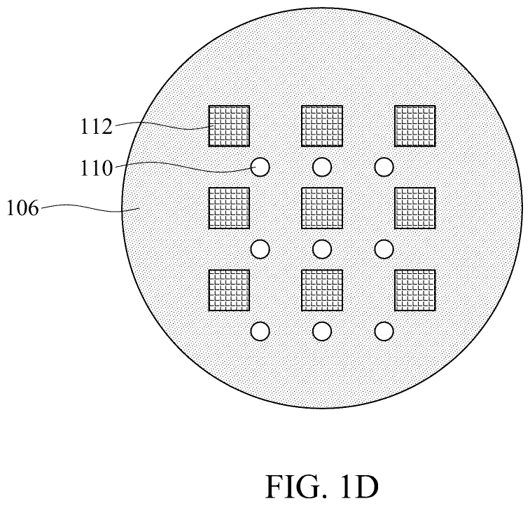

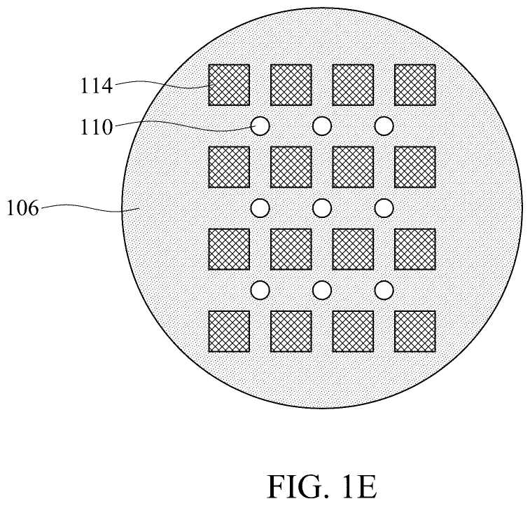

FIGS. 1A and 1B illustrate a probe card 102 configured for testing multiple dies mounted to a multiple-SDT structure 103 according to various embodiments. FIG. 1A is a vertical cross-sectional view of the probe card 102 before testing the dies 116 mounted on the multiple SDT structure 103. FIG. 1B is a vertical cross-sectional view of the probe card 102 making contact with the dies 116 to perform the SDT.

The probe card 102 may include a printed circuit board (PCB) 105, a substrate 107, needles 104, and a positioning device 150. During SDT, the positioning device 150 may move the probe card 102 such that the needles 104 make contact with the dies 116 in the testing location 10, as shown in FIG. 1B. The PCB 105 may route signals from the test system to analysis or additional testing systems such as implemented in a SDT controller 142. The positioning device 150 may be controlled by the SDT controller 142 by activation control signaling 144. The SDT controller 142 may control the positioning device 150 to move the probe card 102 based on testing inputs. The PCB 105 and the substrate 107 may provide mechanical support for the needles 104 to ensure proper and precise alignment with dies while also maintaining durability and long-term reliability of the probe card 102. Further, the PCB 105 may integrate with other testing equipment, such as automatic testing equipment (not shown), to provide efficient and reliable testing.

The substrate 107 may be formed of a multilayer organic (MLO) substrate such as organic dielectric layers, copper, laminates, magneto-dielectric materials, or other appropriate materials. The substrate 107 may improve the signal transmission between the dies 116 and the PCB 105 by offering improved electrical performance. The PCB 105 may also include layer structures that allow for intricate electrical signal routing to support testing of advanced dies 116 that include high pin counts or dense circuitry. Further, the substrate 107 may be formed of materials with high thermal absorption capacity. The substrate 107 may provide mechanical support for the needles 104 while ensuring proper alignment of the needles 104 during contact with the dies 116.

The needles 104 may be electrically connected to the PCB 105 and embedded in the substrate 107. The PCB 105 and substrate 107 may provide the structural support to ensure the proper alignment and securement of the needles 104 placement. As shown in FIG. 1B, the needle 104 may make contact with dies 116 located in the testing location 190 and send electrical signals to the PCB 105 during SDT.

As shown in FIG. 1C, in some embodiments the probe card 102 may include six needles 104, enabling testing of up to six dies 116 at a time. While six needles 104 are shown, in some embodiments, the probe card 102 may include less than six needles or more than six needles. By including multiple needles 104, multiple dies may be tested simultaneously and increase testing efficiency. For example, as shown in FIG. 1C, six dies 116 may be tested simultaneously. In various embodiments, the substrate 107 may have dimensions of about 50 mm by 50 mm, 100 mm by 100 mm, 150 mm by about 150 mm, 50 mm by 100 mm, 100 mm by 150 mm, or any combination of width and lengths in between.

FIGS. 1A and 1B show a multiple SDT structure 103. The multiple SDT structure 103 may be configured to enable testing multiple dies simultaneously, thereby significantly shortening overall testing time and improving overall efficiency. The multiple SDT structure 103 may include an alignment stage 118. The alignment stage 118 may be a substrate (e.g., silicon) or other appropriate supporting structure. A cold plate 106 may be located above the alignment stage 118. In some embodiments, the cold plate 106 may be formed of a material with a high thermal conductivity such as aluminum, copper, or other appropriate materials. The cold plate 106 may be designed to efficiently transfer heat away from the dies 116 thereby ensuring the dies 116 remain within a desired temperature range. The cold plate 106 may facilitate managing the temperature of the dies 116 in conjunction with a heat sink or heat source during SDT. For example, the cold plate 106 may maintain a specific temperature that may be lower than the operating temperature of the dies during SDT. By maintaining a lower temperatures in the dies, the cold plate 106 may prevent overheating of the dies during SDT.

The cold plate 106 may include a vacuum channel 108 with sub-channels 110 that are configured to form a partial vacuum under each die to hold and secure the dies 116 in position during SDT via a suction force. Each die 116 may be associated with a vacuum sub-channel 110 (e.g., the number of dies 116 is equal to the number of vacuum sub-channels 110). The vacuum 108 and vacuum sub-channels 110 may have a small diameter thereby ensuring contact between the cold plate 106 and the dies 116. In other words, any air gaps between the cold plate 106 and the dies 116 is minimized or eliminated to reduce thermal conductivity of the interface between the cold plate 106 and the dies 116. By securing the dies 116 in position, the vacuum channel 108 may aid in maintaining proper thermal contact between the dies 116 and the cold plate 106. As a result, the vacuum channel 108 may aid in minimizing thermal resistance and ensure efficient heat transfer between the dies 116 and the cold plate 106.

The cold plate 106 may be designed with adjustable thermal conductivity areas. Each adjustable thermal conductivity area may include a cooling control system to adjust the cooling capabilities of a portion or the entirety of the cold plate 106. Further, each die 116 may include a thermal sensor configured to measure the junction temperature of each die 116 during operations as well as during SDT. The temperature detected by on-die thermal sensors may also be sent to the SDT controller 142. The SDT controller 142 may trigger an appropriate action such as turning on or off the heaters 112, cooling operations of the cold plate 106, pausing or stopping SDT, or other appropriate actions based on the combination of temperature data from sensors 114 within the cold plate 106 and/or data from on-die thermal sensors within dies 116.

The cold plate 106 may further include a heater 112 positioned and configured to apply heat to dies, as shown in FIG. 1D. As shown, nine heaters 112 may be positioned through the cold plate 106, however, in some embodiments, more or fewer heaters may be present. The heaters 112 may be distributed substantially evenly through the cold plate 106 to provide uniform heating. The heaters 112 may be staggered and evenly distributed between the vacuum sub-channels 110 associated with each die 116.

The heaters 112 may be electrically connected to the SDT controller 142 through heater control leads or electrical conductors 148. The SDT controller 142 may control or provide power to the heaters 112 to turn on or turn off. In some embodiments, there may be more heaters 112 than dies 116. The heaters 112 may be configured and controlled to generate heat to raise the dies 116 to a specific temperature during SDT.

In some testing instances, the heaters 112 may generate sufficient heat to raise the temperature of dies 116 to at least about 125° C. By heating the dies 116, the heater 112 may apply thermal stress on the dies 116 to identify potential weaknesses and failures of the dies 116. The dies failing such thermal stress testing may be removed, ensuring reliability and durability of the dies 116 prior to packaging. Additionally, the heater 112 may be utilized to alternately heat and cool the dies 116 during SDT. Temperature cycling during SDT may test the stability of the dies 116 to withstand temperature fluctuations. During temperature cycling, the heaters 112 and cold plate 106 may be used to fluctuate the temperature of the dies 116 between about −10° C. to about 65° C. within about a minute. Further, the heaters 112 may reduce test time by heating the dies 116 to the testing temperature at a faster rate.

Additionally, the multiple SDT structure 103 may include sensors 114, such as a plurality of thermal sensors, are positioned and configured to measure temperature of or near dies 116. In some embodiments, the sensors 114 and heaters 112 may be substantially aligned or, alternatively, have no physical location correlation. The sensors 114 may be staggered and evenly distributed between the vacuum sub-channels 110 associated with each die 116. The sensors 114 may be electrically connected to the SDT controller 142 through sensor data leads 146. The sensors 114 may collect and send temperature data from the heaters 112 to the SDT controller 142. Based on the temperature data, the SDT controller 142 may trigger the heaters 114 to turn on or off.

In the embodiment shown in FIG. 1E, the cold plate 106 may include multiple sensors 114. For example, as shown, sixteen sensors 114 may be distributed within the cold plate 106; however, more than sixteen or less than sixteen sensors 114 may be embedded within the cold plate 106. The sensors 114 may be distributed substantially evenly through the cold plate 106 to provide uniform temperature sensing. The temperature of each die 116 may be measured by at least one sensor embedded in the cold plate 106. In some embodiments, each die 116 may be associated with four individual sensors in the sensor 114. In some embodiments, the sensor 114 may constantly or intermittingly monitor the temperature of the dies 116. Temperature measurements by the sensor 114 may be used (e.g., by a temperature processor or the controller 142) to trigger the heaters 112 to turn off, turn on, or change power level. By sensing a specified temperature or temperature range, the sensors 114 may aid in triggering the heaters 112. By turning on or off the heater 112, thermal damage to the dies 116 may be prevented resulting in reliable performance of the dies 116 under different thermal conditions.

In some embodiments, the sensor 114 may further detect force to ensure the needles 104 make appropriate contact with the dies 116 and perform environmental monitoring (e.g., detect humidity) to ensure optimal testing conditions. The sensors 114 may send sensor information to the SDT controller 142 through the sensor data leads 146 and the SDT controller 142 may trigger actions based on the sensor information. For example, the SDT controller 142 may trigger the positioning device 150 to move the probe card 102 or turn the heater 112 on or off.

Integrating the heaters 112 and sensors 114 in the cold plate 106 may improve thermal management. For example, the heaters 112 and sensors 114 may connect to a control system 142 to ensure proper temperature control of the multiple SDT structure 103 and adjust the temperature as necessary based on testing conditions. Further, the heaters 112 and sensors 114 may provide more precise and intricate temperature control of certain areas of the multiple SDT structure 103.

The multiple SDT structure 103 shown in FIGS. 1A and 1B significantly shortens the testing time of the dies 116 by testing multiple dies simultaneously thereby increasing efficiency. Additionally, by separating the dies 116 and directly connecting the dies 116 to the cold plate 106, heat produced from one die 116 may not affect another die 116. The heaters 112 and sensors 114 integrated into the cold plate 106 increase the sensitivity of the multiple SDT structure 103 to temperature changes and therefore enhances overall temperature control. Because the dies 116 are secured to the cold plate 106 using the sub-channels 110, the size of the dies 116 may vary and therefore have limited die size restrictions.

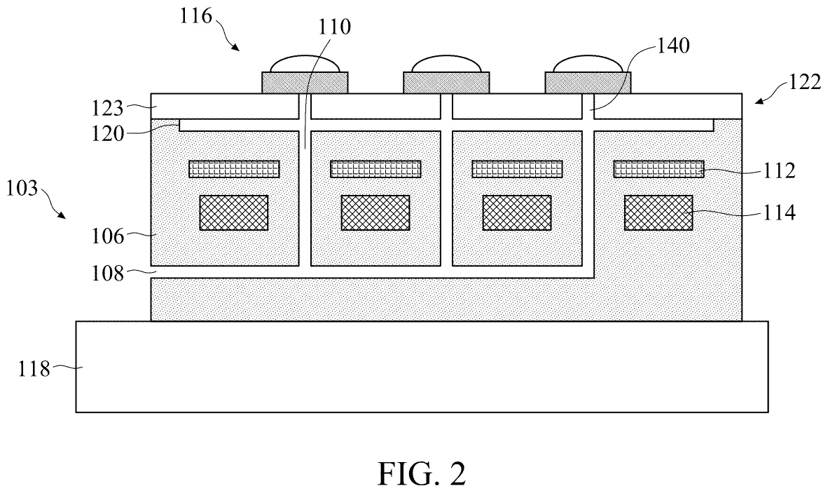

FIG. 2 illustrates an alternative multiple SDT structure 103 according to some embodiments. As shown in FIG. 2, the multiple SDT structure 103 may further include a multiple singulated die holder 122. The multiple singulated die holder 122 may allow for dies 116 to be pre-loaded while other dies are being tested, thereby improving testing time. The multiple singulated die holder 122 may include a substrate 123 formed of a material with thermal conduction properties such as silicon, copper, ceramics, or other appropriate material. These materials may enable the multiple singulated die holder 122 to further improve heat dissipation during SDT.

The multiple singulated die holder may configured to hold the plurality of dies in testing locations 190 through suction forces provided by vacuum sub-channels 140 positioned to provide suction force to each testing location on the holder. The multiple singulated die holder 122 may be secured to the cold plate 106 by force from the vacuum channel 108 through a securement vacuum sub-channel 120. The vacuum sub-channels 140 pass through the multiple singulated die holder 122 to connect with the securement vacuum sub-channels 120 to provide suction forces from the vacuum sub-channels 110 to secure the dies 116 to the multiple singulated die holder 122.

The multiple singulated die holder 122 may expand the cold plate 106 to accommodate more dies 116 for testing at a time. The multiple singulated die holder 122 may be used in situations where high thermal conductivity is needed or preferred during SDT. Additionally, the multiple singulated die holder 122 shown in FIG. 2 may be replaceable and therefore may easily accommodate a variety of die shapes and sizes. Further, because the multiple singulated die holder 122 are interchangeable, this permits pre-loading one holder with dies 116 while other dies are being tested on another holder, thereby further improving testing time and efficiency. Additionally, the ability to use multiple singulated die holders 122 may improve production space by reducing the number of multiple SDT structures 103 required for testing. In case of damage, the singulated die holder 122 may easily be replaced, thereby reducing costs to repair the multiple SDT structure 103.

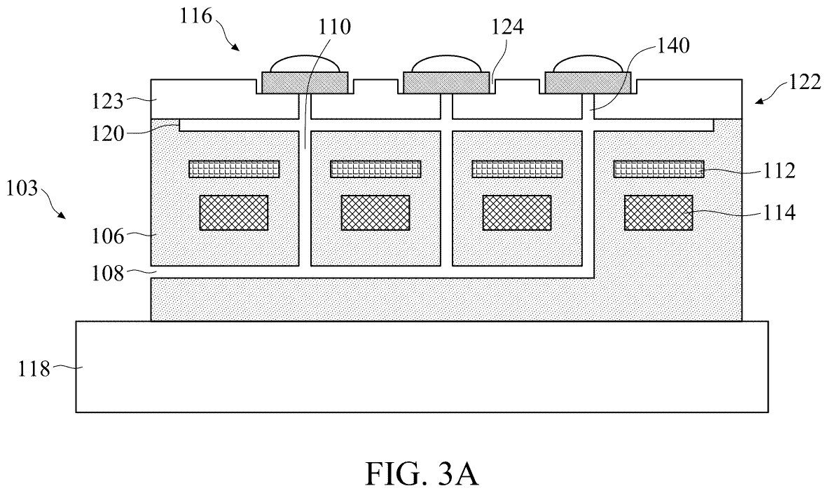

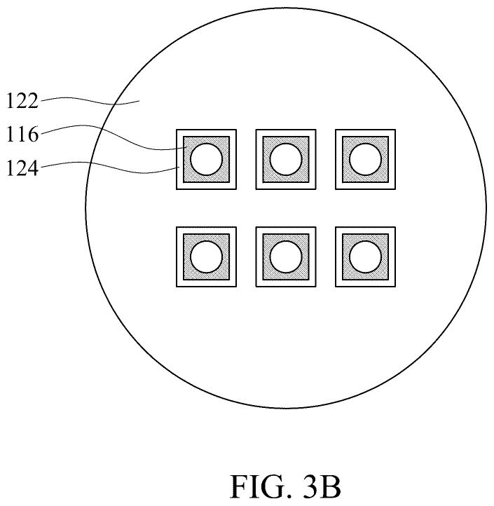

FIG. 3A illustrates another embodiment of the multiple singulated die holder 103 that includes die grooves 124 located within the substrate 123 defining die testing locations 190. The multiple singulated die holder may include vacuum sub-channels 140 positioned between die grooves 124 to secure dies in each testing location via suction forces. The multiple singulated die holder 122 may be secured to the cold plate 106 by suction force from the vacuum channel 108 through a securement vacuum sub-channel 120. Each die groove 124 may be connected to a vacuum sub-channel 110. The vacuum sub-channel 110 may secure the dies 116 in place during the SDT. The die grooves 124 may further separate the dies 116 to reduce chances that the heat produced by the dies will affect one another during the SDT. In some embodiments, the die grooves 124 may be patterned or etched in the substrate 123. The dies 116 may be located within the die grooves 124. The die grooves 124 may have a height similar to the height of the dies 116. For example, the die grooves 124 may have a height ranging from about 200 mm to about 720 mm.

By creating the die grooves 124, the thickness of the multiple singulated die holder 122 may be increased resulting in better heat dissipation and structural support to the dies 116. Additionally, the die grooves 124 may provide further thermal separation of the dies 116 thereby reducing thermal conduction between dies during testing. In other words, the die grooves 124 prevent heat generated by dies 116 from affecting other dies 116. Further, the die grooves 124 within the multiple singulated die holder 122 may provide higher thermal conductivity compared to the singulated die holder 122 of the embodiment illustrated in FIG. 2.

FIG. 3B illustrates a top view of the multiple singulated die holder 122 shown in FIG. 3A. As shown, each die 116 is located in an die groove 124 within the substrate 103. As shown, the multiple singulated die holder 122 may have at least six die grooves 124, however, the multiple singulated die holder 122 may include more than six die grooves 124. Each die groove 124 may be associated with a vacuum sub-channel 110 (not shown). Each die groove 124 may have dimensions of about 5 mm by about 5 mm, about 5 mm by about 20 mm, about 10 mm by about 25 mm, about 10 mm by about 10 mm, about 20 mm by about 20 mm, about 30 mm by about 30 mm, about 20 mm by about 30 mm, about 30 mm about 40 mm, or about 40 mm by 40 mm. Additionally, the dimensions of the area covered by the die grooves 124 may be about 100 mm by about 100 mm, about 100 mm by about 200 mm, about 200 mm by 200 mm, about 200 mm by about 300 mm, or about 300 mm by 300 mm.

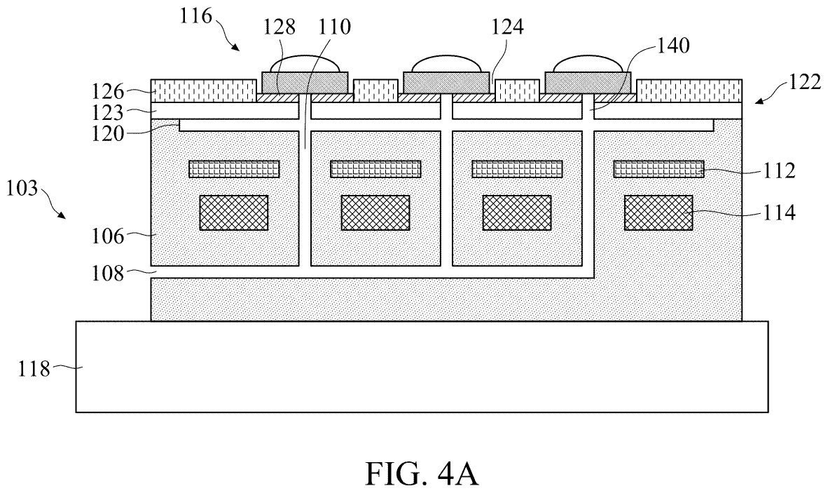

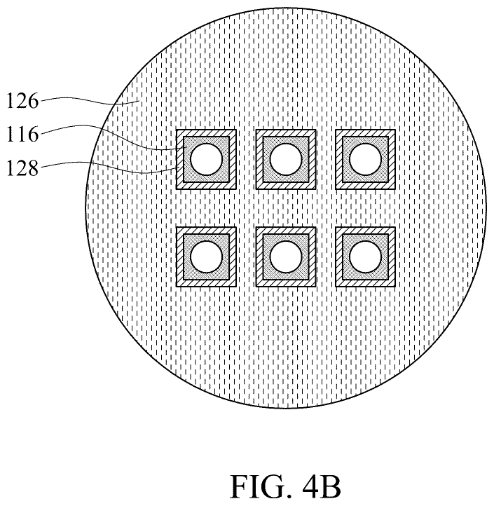

FIG. 4A illustrates another embodiment of the multiple singulated die holder 122 with multiple layers with different thermal conductivities thereby reducing thermal interactions between dies. In some embodiments, the multiple singulated die holder 122 may include a low thermal conductivity layer 126 is located above the substrate 103 to further thermally isolate dies. The multiple singulated die holder 122 may be secured to the cold plate 106 by suction force from the vacuum channel 108 through a securement vacuum sub-channel 120. In some embodiments, the low thermal conductivity layer 128 may be formed of a material with a conductivity of at most 0.05 W/m*K. For example, the low thermal conductivity layer 128 may be formed of glass, ceramic, foamed rigid urethane, or other appropriate low thermal conductive materials.

Additionally, a high thermal conductivity layer 128 may be located within each of the die grooves 124 to improve thermal conduction from each die to the cold plate. In some embodiments, the high thermal conductivity layer 126 may be formed of a material with a conductivity of a least 80 W/m*K. For example, the high thermal conductivity layer 126 may be formed of diamond, silver, copper, gold, aluminum, iron, or other appropriate high thermal conductive materials.

The addition of the high thermal conductivity layer 126 and the low thermal conductivity layer 128 in the multiple singulated die holder 122 reduces thermal interactions between the dies 116. The heat generated by each die 116 will be insulated from other dies 116 by the low thermal conductivity layer 126 while being conducted into the cold plate 106 through the high conductivity layer 128. As a result, the multiple singulated die holder 122 may resist thermal interference between the dies 116.

FIG. 4B illustrates a top view of the multiple singulated die holder 122 shown in FIG. 4A. As shown, the dies 116 are positioned on top of a high thermal conductivity layer 128 and surrounded by a low thermal conductivity layer 126. The multiple singulated die holder 122 may have similar dimensions as described in FIG. 3B. As shown, the multiple singulated die holder 122 may have at least six die grooves 124, however, the multiple singulated die holder 122 may include more than six die grooves 124. Each die groove 124 may be associated with a vacuum sub-channel 110 (not shown).

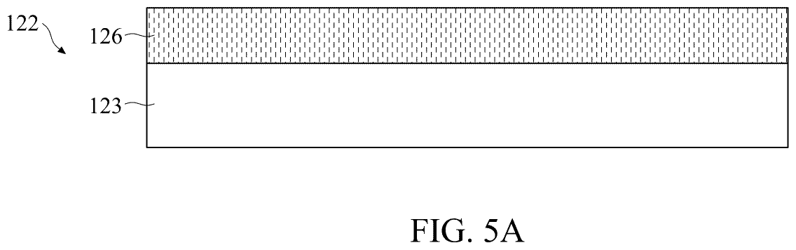

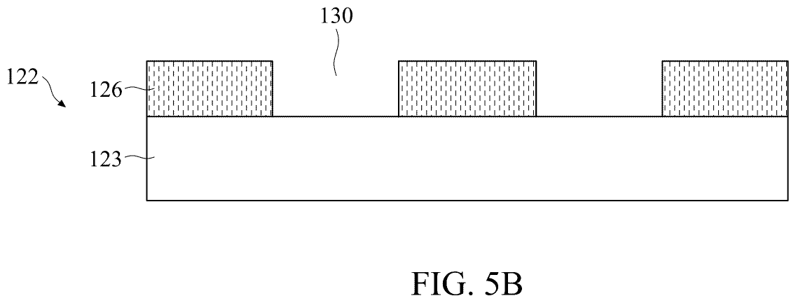

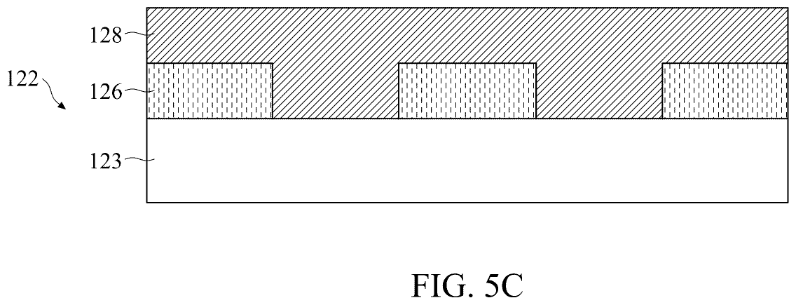

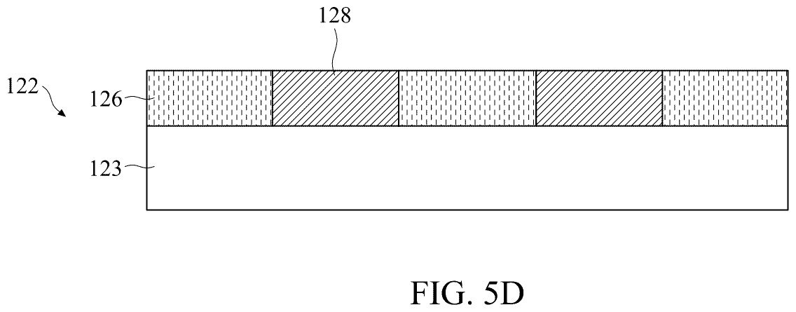

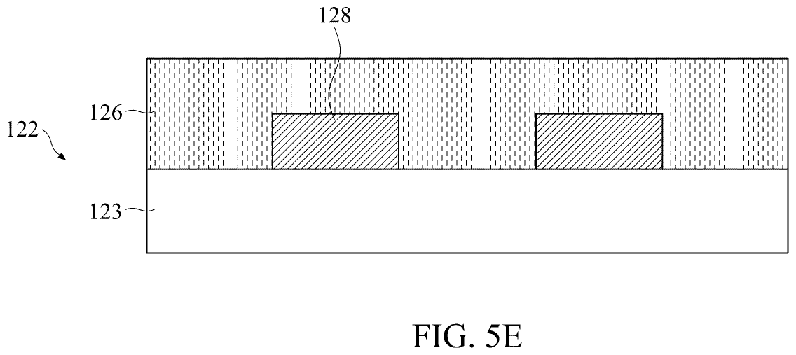

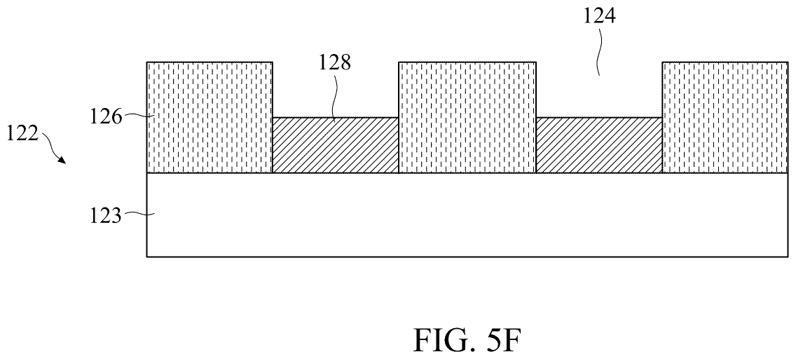

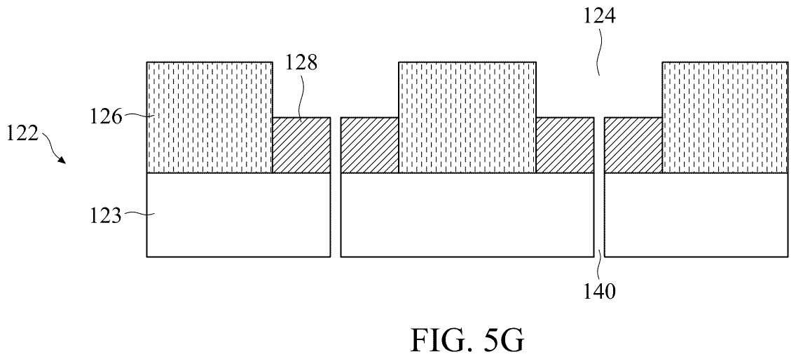

FIGS. 5A through 5F illustrate intermediate structures that are formed in the process of making the multiple singulated die holder 122 shown in FIG. 4A according to some embodiments. Initially, as shown in FIG. 5A, a low thermal conductivity layer 126 may be formed above the substrate 123. The low thermal conductivity layer 126 may be formed by deposition methods (e.g., chemical vapor deposition, physical vapor deposition, or atomic vapor deposition) or plating methods (e.g., electroplating).

FIG. 5B illustrates patterning of the low thermal conductivity layer 126. Patterning may involve photolithography, patterned etching, or laser milling processes. The patterning may form cavities 130 within the low thermal conductivity layer 126 exposing the substrate 123. Optionally, the cavities 130 may be polished by a chemical mechanical polishing technique.

FIG. 5C illustrates the intermediate operation of forming a high thermal conductivity layer 128 above the low thermal conductivity layer 126 and in the cavities 130. Similar to forming the low thermal conductivity layer 126, the high thermal conductivity layer 128 may be formed using deposition methods or plating methods.

FIG. 5D illustrates the intermediate operation of thinning the high thermal conductivity layer 128. The high thermal conductivity layer 128 may be thinned to be co-planar with the low thermal conductivity layer 126, such as by chemical mechanical polishing, etching, laser ablation, or ion milling. Optionally, the top surface may be polished or cleaned to create a smooth surface.

FIG. 5E illustrates the intermediate operation of applying an additional low thermal conductivity material to the low thermal conductivity layer 126. Similarly, as above, the additional low thermal conductivity material may be deposited using deposition or plating methods.

FIG. 5F illustrates the intermediate operation of patterning the low thermal conductivity layer 126. The patterned low thermal conductivity layer 126 forms the die grooves 124 with the high thermal conductivity layer 128 located at the bottom surface of the die grooves 124. Patterning may involve photolithography, patterned etching, or laser milling processes. The die grooves 124 may have a height of about 200 mm to about 720 mm.

FIG. 5G illustrates the intermediate operation of forming the vacuum sub-channels 140 through the die grooves 124 and substrate 123. In some embodiments, the vacuum sub-channels 140 may be formed by a laser drilling or etching process. The vacuum sub-channels may be substantially aligned to a center of the die grooves 124. The vacuum sub-channels 140 may secure the dies in place using suction forces.

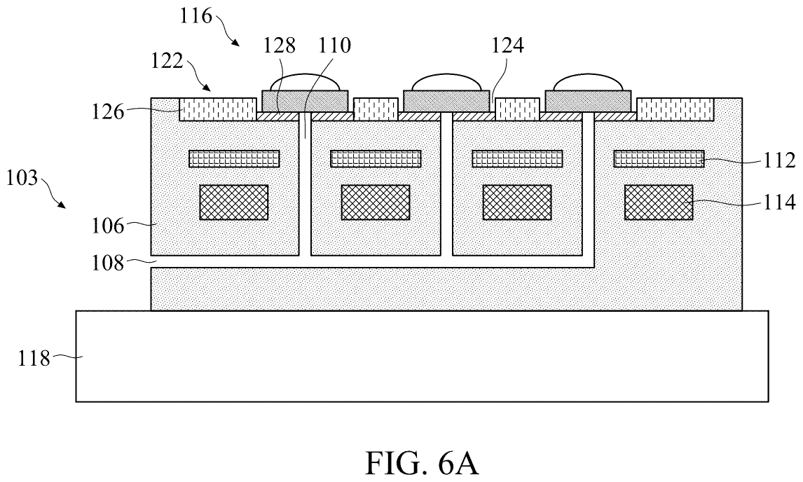

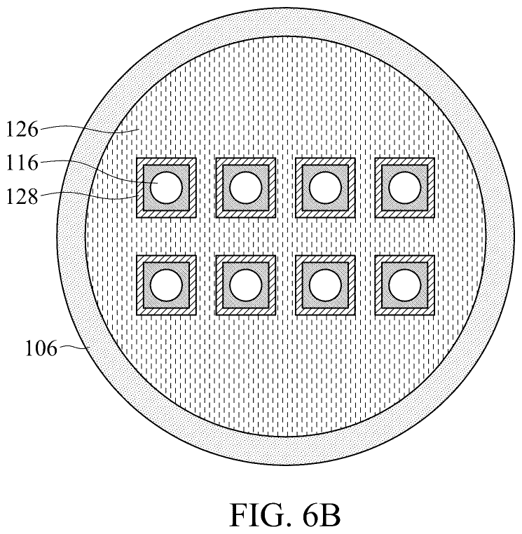

FIG. 6A illustrates another alternative embodiment of the multiple singulated die holder 122. In this embodiment, the multiple singulated die holder 122 is incorporated within the cold plate 106. In other words, the multiple singulated die holder 122 is formed in the cold plate 106 and the low conductivity material layer 126 is in direct contact on three sides or partially surrounded by the cold plate 106.

The multiple singulated die holder 122 may resist thermal interference due to the high conductivity material layer 128 and the low conductivity material layer 126 which ensures heat generated by the dies 116 does not affect other dies 116. Additionally, because the multiple singulated die holder 122 is incorporated into the cold plater 106, this embodiment is suitable for dies 116 of the same or a consistent size.

FIG. 6B illustrates a top view of the multiple singulated die holder 122 shown in FIG. 6A. As shown, the die 116 is located above the high conductivity material layer 128 which is surrounded by the low conductivity material layer 126. The diameter of the low conductivity material layer 126 may be about 100 mm, about 200 mm, about 300 mm, or about 400 mm. Surrounding the low conductivity material layer 126 is the cold plate 106. As shown, the multiple singulated die holder 122 may have at least six die grooves 124; however, the multiple singulated die holder 122 may include more than six die grooves 124. Each die groove 124 may be associated with a vacuum sub-channel 110 (not shown).

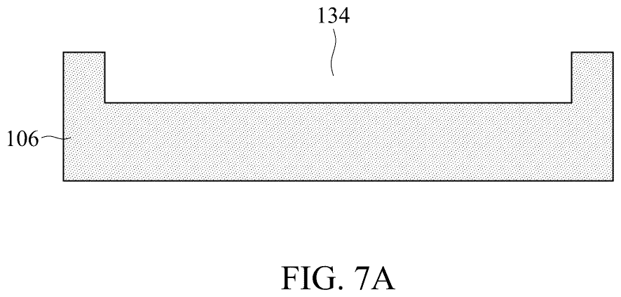

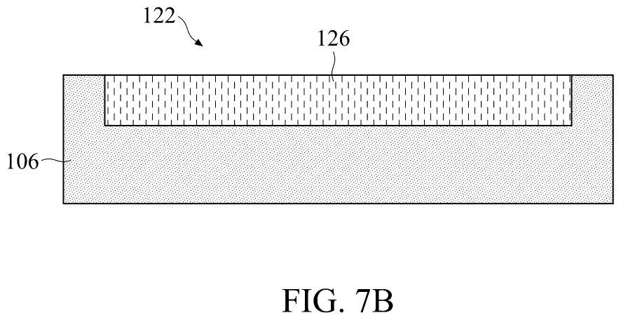

FIGS. 7A and 7B illustrate operations for forming the multiple singulated die holder 122 in the cold plate 106. Initially, as shown in FIG. 7A, the cold plate 106 may be patterned to create a cavity 134. Patterning may involve photolithography, patterned etching, or laser milling processes. Optionally, the cavity may be polished using chemical mechanical polishing to create a smooth surface.

FIG. 7B illustrates operations for forming the low thermal conductivity material layer 126 within the cavity 134. The low thermal conductivity material layer 126 may be deposited or plated in the cavity 134. Following the formation of the low thermal conductivity material layer 126, the operations shown in 5B through 5F may be performed to form the die grooves 124.

The following discussion now refers to a number of methods and operations. Although the method operations are discussed in specific orders or are illustrated in a flow chart as being performed in a particular order, no order is required unless expressly stated or required because an operation is dependent on another operation being completed prior to the operation being performed.

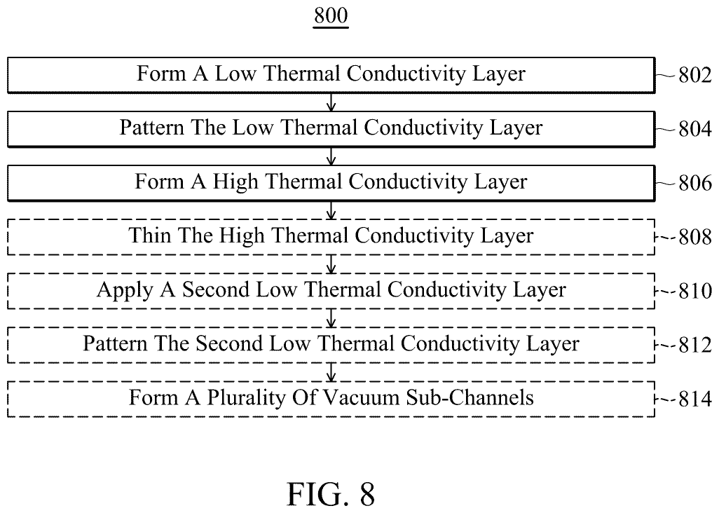

Embodiments are now described with reference to FIG. 8, which is a flow diagram of an example method 800 for forming a multiple singulated die holder 122 that includes a low thermal conductivity layer 126. Referring to FIGS. 4A, 5A, 6A, 7A, and 8, in operation 802, the low thermal conductivity layer 126 may be formed above a substrate 123 or within a cavity 134 in the cold plate 106. In some embodiments, the low thermal conductivity layer 126 may be deposited or plated. The low thermal conductivity layer 126 may be formed of a material with a thermal conductivity below or equal to 0.05 W/m*K. For example, the low thermal conductivity layer 126 may be formed of air, glass, or foamed rigid urethane.

Operation 804 may include patterning the low thermal conductivity layer 126 to form die grooves 124. Referring to FIGS. 4A, 5B, 6A, and 8, in operation 804, the low thermal conductivity layer 126 may be patterned to form cavities 130 corresponding to the die grooves 124. In some embodiments, the cavity may further be polished using chemical mechanical polishing.

Operation 806 may include forming a high thermal conductivity layer 128. Referring to FIGS. 4A, 5D, 6A, and 8, in operation 806, the high thermal conductivity layer 128 may be formed within the cavities 130 and located in the die grooves 124. In some embodiments, the high thermal conductivity layer 128 may be deposited or plated. The high thermal conductivity layer 128 may be formed of a material with a thermal conductivity above or equal to 80 W/m*K. For example, the high thermal conductivity layer 128 may be formed of diamond, copper, silver, gold, aluminum, or iron.

Optional operation 808 may include thinning the high thermal conductivity layer 128. Referring to FIGS. 4A, 5D, 6A, and 8, in optional operation 808, the high thermal conductivity layer 128 may be thinned to be co-planar with the low thermal conductivity layer 126. Additionally, the top surface may be further smoothed.

Optional operation 810 may include applying a second low thermal conductivity layer 126 above the low thermal conductivity layer 126 and high thermal conductivity layer 128. Referring to FIGS. 4A, 5E, 6A, and 8, in operation 810, the low thermal conductivity layer 126 may be formed above the low thermal conductivity layer 126 and the high thermal conductivity layer 128.

Optional operation 812 may include patterning the low thermal conductivity layer 126 such that the second low thermal conductivity layer 126 is above the low thermal conductivity layer 126 and the high thermal conductivity layer 128 is located in the die grooves 124. Referring to FIGS. 4A, 5F, 6A, and 8, in operation 812, the low thermal conductivity layer 126 may be patterned to form the die grooves 124. The high thermal conductivity material layer 128 may be located at a bottom surface of the die grooves 124 and surrounded by the low thermal conductivity material layer 126. In some embodiments, the die grooves may have a height of about 200 mm to about 720 mm.

Operation 814 may include forming a plurality of vacuum sub-channels 110. Referring to FIGS. 1A, 2, 3A, 4A, 6A, and 8, in operation 814, each die 116 may be connected to a vacuum sub-channel 110. The vacuum sub-channels 110 may secure and hold the dies 116 in place during the SDT. Further, the vacuum sub-channels 110 may secure the multiple singulated die holder 123 to the cold plate 106.

Referring to all drawings and according to various embodiments, a die testing structure 103 may include a cold plate 106, in which the cold plate 106 includes a plurality of sensors 114, a plurality of heaters 112, wherein each heater 112 is located below a corresponding sensor 114, and a vacuum channel 108 with a plurality of sub-channels 110 located between each sensor 114, and a vacuum channel 108 with a plurality of vacuum sub-channels 110 located between each sensor 114, in which the plurality of sensors 114, the plurality of heaters 112, and the plurality of vacuum sub-channels 110 form a plurality of testing locations 190 configured to receive a plurality of dies 116.

In some embodiments, the vacuum sub-channels 110 are configured to secure the dies 116 to the cold plate 106. In some embodiments, the die testing structure further includes a multiple singulated die holder 122 configured to hold the plurality of dies 116 in testing locations 190, in which the multiple singulated die holder 122 is configured to be positioned on the cold plate 106 and includes vacuum sub-channels 140 that connect to the vacuum sub-channels 110 in the cold plate and are positioned to secure dies in each testing location via suction forces. In some embodiments, the die testing structure further includes a plurality of die grooves 124 to accommodate dies 116 during testing. In some embodiments, the plurality of die grooves 124 are located within the cold plate 106. In some embodiments, the die testing structure further includes a multiple singulated die holder 122 located between the cold plate 106 and the dies, in which a plurality of die grooves 124 are included within the multiple singulated die holder 122. In some embodiments, the die testing structure further includes a high thermal conductivity layer 128 and a low thermal conductivity layer 126, in which the plurality of die grooves 124 are formed within the low thermal conductivity layer 126 and the high thermal conductivity layer 128 is located within each of the plurality of die grooves 124. In some embodiments, the die testing structure further includes a substrate 123, in which the low thermal conductivity layer 126 is located above the substrate 123. In some embodiments, the high thermal conductivity layer 126 has a thermal conductivity of at least 80 W/m*K. In some embodiments, the low thermal conductivity layer 128 has a thermal conductivity of at most 0.05 W/m*K.

In some embodiments, a multiple singulated die holder 122 includes a low thermal conductivity layer 126 and a plurality of die grooves 124 located within the low thermal conductivity layer 126, in which each die groove 124 includes a high thermal conductivity layer 128 and each die groove 124 is configured to receive an die 116 located above each high thermal conductivity layer 128.

In some embodiments, the multiple singulated die holder further includes a plurality of vacuum sub-channels 110, each vacuum sub-channel 110 is configured to be connected to a vacuum source, wherein each die groove 124 is connected to one of the plurality of vacuum sub-channels 110. In some embodiments, the multiple singulated die holder further includes a cold plate 106, wherein the low thermal conductivity layer 126 is located in the cold plate 106. In some embodiments, the multiple singulated die holder further includes a substrate 123 located between the cold plate 106 and the low thermal conductivity layer 126. In some embodiments, the low thermal conductivity layer 126 is located above a substrate 123. In some embodiments, the high thermal conductivity layer 126 has a thermal conductivity of at least 80 W/m*K. In some embodiments, the low thermal conductivity layer 128 has a thermal conductivity of at most 0.05 W/m*K.

Some embodiments include a method for forming a singulated die holder 122 that includes forming a low thermal conductivity layer 126, patterning the low thermal conductivity layer 126 to form die grooves 124, forming a high thermal conductivity layer 128 in the die grooves 124, and forming a plurality of vacuum sub-channels 110, wherein each vacuum sub-channel 110 is connected to each die groove 124.

In some embodiments, forming the high thermal conductivity layer 128 further includes thinning the high thermal conductivity layer 128 to be co-planar with the low thermal conductivity layer 126. In some embodiments, the method further includes applying a second low thermal conductivity layer 126 above the low thermal conductivity layer 126 and high thermal conductivity layer 128. In some embodiments, the method further includes patterning the second low thermal conductivity layer 126 such that the second low thermal conductivity layer 126 is above the low thermal conductivity layer 126 and the high thermal conductivity layer 128 is located in the die grooves 124.

Various embodiments disclosed herein may provide various advantages and improvements. For example, various embodiments disclosed herein may include singulated die holders that carry multiple dies. Therefore, various embodiments disclosed herein may significantly reduce testing time of testing multiple dies. Additionally, various embodiments disclosed herein enhance thermal control capabilities by integrating a sensor and heater in the cold plate. By removing the heater layer, various embodiments maintain precise temperature control during testing. As a result, various embodiments reduce thermal stress, improve thermal expansion, minimize testing defects, and improve performance and reliability of the dies.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the scope of the present disclosure, and that they may make various changes, substitutions, and alterations herein without departing from the scope of the claims.

What is claimed is:

1. A die testing structure, comprising:
a cold plate, wherein the cold plate comprises:
a plurality of sensors;
a plurality of heaters, wherein each heater is located below a corresponding sensor; and
a vacuum channel with a plurality of vacuum sub-channels located between each sensor;
wherein the plurality of sensors, the plurality of heaters, and the plurality of vacuum sub-channels form a plurality of testing locations configured to receive a plurality of dies.

2. The die testing structure of claim 1, wherein the vacuum sub-channels are configured to secure the dies to the cold plate via suction forces.

3. The die testing structure of claim 1, further comprising a multiple singulated die holder configured to hold the plurality of dies in testing locations, wherein the multiple singulated die holder is configured to be positioned on the cold plate and includes vacuum sub-channels positioned to secure dies in each testing location via suction forces.

4. The die testing structure of claim 1, further comprising a plurality of die grooves to accommodate dies during testing.

5. The die testing structure of claim 4, wherein the plurality of die grooves are located within the cold plate.

6. The die testing structure of claim 4, further comprising a multiple singulated die holder located between the cold plate and the dies, wherein the plurality of die grooves are formed within the multiple singulated die holder.

7. The die testing structure of claim 4, further comprising a high thermal conductivity layer and a low thermal conductivity layer, wherein the plurality of die grooves are formed within the low thermal conductivity layer and the high thermal conductivity layer is located within each of the plurality of die grooves.

8. The die testing structure of claim 7, further comprising a substrate, wherein the low thermal conductivity layer is located above the substrate.

9. The die testing structure of claim 7, wherein the high thermal conductivity layer has a thermal conductivity of at least 80 W/m*K.

10. The die testing structure of claim 7, wherein the low thermal conductivity layer has a thermal conductivity of at most 0.05 W/m*K.

11. A die holder, comprising:
a low thermal conductivity layer; and
a plurality of grooves located within the low thermal conductivity layer, wherein each die groove includes a high thermal conductivity layer, and each die groove is configured to receive an die located above each high thermal conductivity layer.

12. The multiple singulated die holder of claim 11, further comprising a plurality of vacuum sub-channels, each vacuum sub-channel is configured to be connected to a vacuum source, wherein each die groove is connected to one of the plurality of vacuum sub-channels.

13. The multiple singulated die holder of claim 11, further comprising a cold plate, wherein the low thermal conductivity layer is located within the cold plate.

14. The multiple singulated die holder of claim 11, further comprising a substrate located between a cold plate and the low thermal conductivity layer.

15. The multiple singulated die holder of claim 11, wherein the high thermal conductivity layer has a thermal conductivity of at least 80 W/m*K.

16. The multiple singulated die holder of claim 11, wherein the low thermal conductivity layer has a thermal conductivity of at most 0.05 W/m*K.

17. A method for forming a singulated die holder, comprising:
forming a low thermal conductivity layer;
patterning the low thermal conductivity layer to form a plurality of die grooves;
forming a high thermal conductivity layer in each of the plurality of die grooves; and
forming a plurality of vacuum sub-channels, wherein each vacuum sub-channel is connected to each die groove.

18. The method of claim 17, wherein forming the high thermal conductivity layer further comprises:
thinning the high thermal conductivity layer to be co-planar with the low thermal conductivity layer.

19. The method of claim 17, further comprising applying a second low thermal conductivity layer above the low thermal conductivity layer and high thermal conductivity layer.

20. The method of claim 19, further comprising patterning the second low thermal conductivity layer such that the second low thermal conductivity layer is above the low thermal conductivity layer and the high thermal conductivity layer is located in the die grooves.
